(19) United States
(12) Patent Application Publication
(10) Pub. No.: US 2002/0084479 A1
(43) Pub. Date: Jul. 4, 2002

(54) High density capacitor using topographic surface

(76) Inventors: Shanjen Pan, Plano, TX (US); Xiaoju Wu, Irving, TX (US); Peter Ying, Plano, TX (US)

Correspondence Address: TEXAS INSTRUMENTS INCORPORATED, P O BOX 655474, M/S 3999, DALLAS, TX, 75265

(21) Appl. No.: 09/998,606

(22) Filed: Nov. 30, 2001

Related U.S. Application Data
(60) Provisional application No. 60/295,725, filed on Jun. 4, 2001.
(60) Provisional application No. 60/259,258, filed on Dec. 31, 2000.

(51) Int. Cl. H01L 27/108

(52) U.S. Cl. 257/303

(57) ABSTRACT

Capacitor area is increased in the vertical direction by forming capacitors on topographic features on the chip. The features are formed during existing process steps. Adding vertical topography increases capacitance per unit area, reducing die size at no added development cost or mask steps.

### BACKGROUND AND SUMMARY OF THE INVENTION

The present invention relates to integrated circuit structures and fabrication methods, and particularly to capacitor structures for mixed signal and analog applications.

### BACKGROUND

Many electronics applications require an integrated circuit that can accept analog signals as input, and process the information so that it can be communicated to another integrated circuit (IC) or user. This usually requires an analog interface on the IC and a digital core to perform signal processing and other digital functions.

For mixed signal product design, as the technology is scaled to smaller and smaller sized, capacitor size (such as a decoupling capacitor) does not decrease as quickly as some other technologies (such as interconnects and other components). Thus the total area occupied by the capacitor grows with respect to the other components and becomes substantially large in mixed signal design technologies, reaching areas of over 40% in some designs.

### Density Improvement for High Performance Capacitor Using Topographic Surface

The present application discloses an improved capacitor and fabrication method. The capacitor is formed over sections of the integrated circuit that have topographic or surface features which extend above and/or below the surface. Forming the capacitor on such features causes the capacitor to have greater surface area, which increases the total capacitance for a given area on the wafer devoted to the capacitor. This increase in capacitance per unit area is gained at no development cost or extra mask steps, and increases the die area significantly.

Advantages of the disclosed methods and structures, in various embodiments, can include one or more of the following:

uses existing process flow—no development cost;

no extra mask steps needed to implement;

die size is reduced about 5-12% in area, and requires only layout modification.

### BRIEF DESCRIPTION OF THE DRAWINGS

The disclosed inventions will be described with reference to the accompanying drawings, which show important sample embodiments of the invention and which are incorporated in the specification hereof by reference, wherein:

FIG. 1 shows a conventional capacitor structure.

FIG. 2 shows a capacitor formed according to the present innovations.

FIGS. 3a-3c show partially fabricated capacitor structures at different stages of fabrication according to a preferred embodiment.

FIGS. 4a-4b show partially fabricated capacitor structures at different stages of fabrication according to the present innovations.

FIGS. 5a-5c show partially fabricated capacitor structures at different stages of fabrication according to a preferred embodiment.

### DETAILED DESCRIPTION OF THE PREFERRED EMBODIMENTS

The numerous innovative teachings of the present application will be described with particular reference to the presently preferred embodiment. However, it should be understood that this class of embodiments provides only a few examples of the many advantageous uses of the innovative teachings herein. In general, statements made in the specification-of the present application do not necessarily delimit any of the various claimed inventions. Moreover, some statements may apply to some inventive features but not to others.

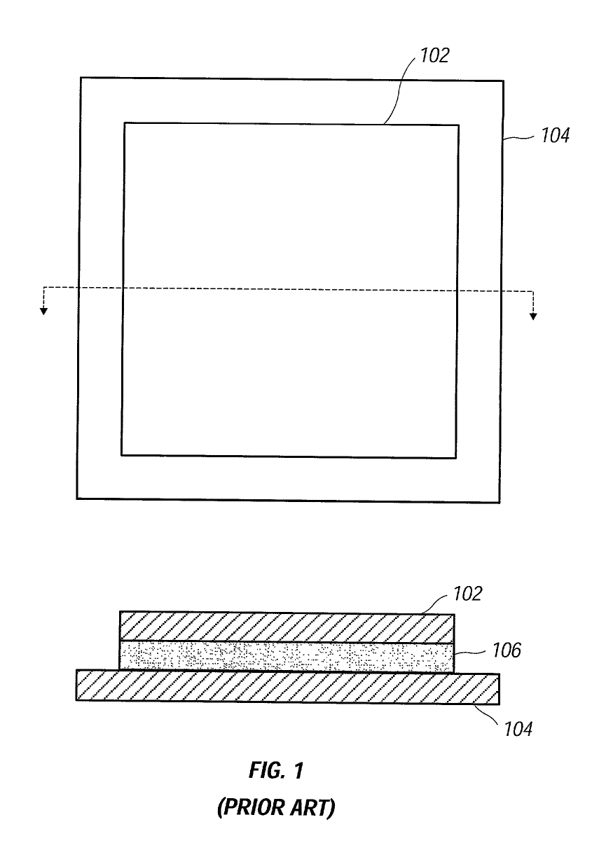

FIG. 1 shows a planar type capacitor. A top and side view are provided. The planar capacitor comprises a top plate 102 and a bottom plate 104, with a dielectric material 106 sandwiched between. The plates are of course made from conductors, such as a metal or polysilicon.

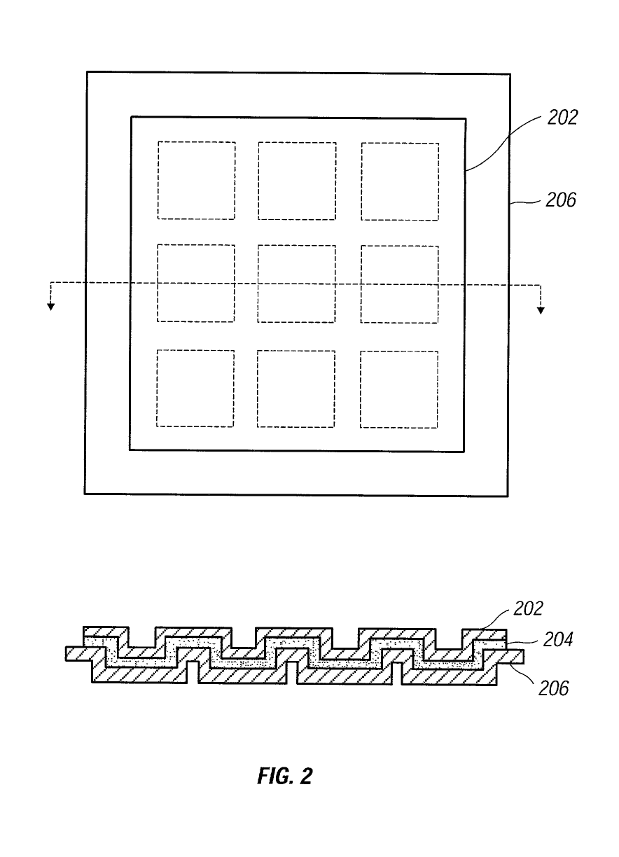

FIG. 2 shows a topographic capacitor according to an embodiment of the present innovations. The top plate 202, dielectric layer 204, and bottom plate 206 are placed on surface features that extend above the planar surface, giving the deposited conductor and dielectric layers added surface area and increasing capacitor density.

The top plate and bottom plates are not planar, but instead have topographic features, or relief features extending above and/or below the surface, that increase the total surface area of the capacitor, thus increasing the total capacitance of the device. In this example, the capacitor is formed over marks placed on the wafer surface during the alignment mark placement phase of processing. These marks in the preferred embodiment provide surface relief or three dimensional features that extend out of and into the plane of the surface on which to form the capacitor, giving it dimension in the vertical direction as well as in the horizontal, as seen in the figure. Both the bottom and top plates are formed over these features, as is shown in the side view. The surface features, or relief features, may extend above the plane, recess into the plane, or both.

In existing processes, process steps are spent on adding alignment marks to the surface of the wafer. This existing process budget is used in the present preferred embodiment to also place features on the surface of the wafer where the capacitors are to be formed. These features provide the topography necessary for making a non-planar capacitor. The layout for placing the alignment marks can be modified to also place the topographic features in the same process steps, requiring modification only in the reticles and pattern layouts and not requiring added process steps. Of course other means can be used to place surface features upon which to form the innovative capacitors in less preferred embodiments. For example, scoring the surface of the wafer with a laser is one possible, though less preferred, alternative for placing relief features on the surface.

There are multiple ways that forming surface topographic features for the capacitors can be implemented into the process. Three example embodiments are discussed for integrating the capacitor formation into existing processes. The first example discusses forming surface features during the process phase in which the alignment marks are formed, called the pole 0 approach. The second example shows forming the surface features during the well oxidation phase, called the well oxidation approach. The third example shows a combination of these two methods, in which the surface features are formed using both aforementioned processes. These will each be discussed in further detail separately below.

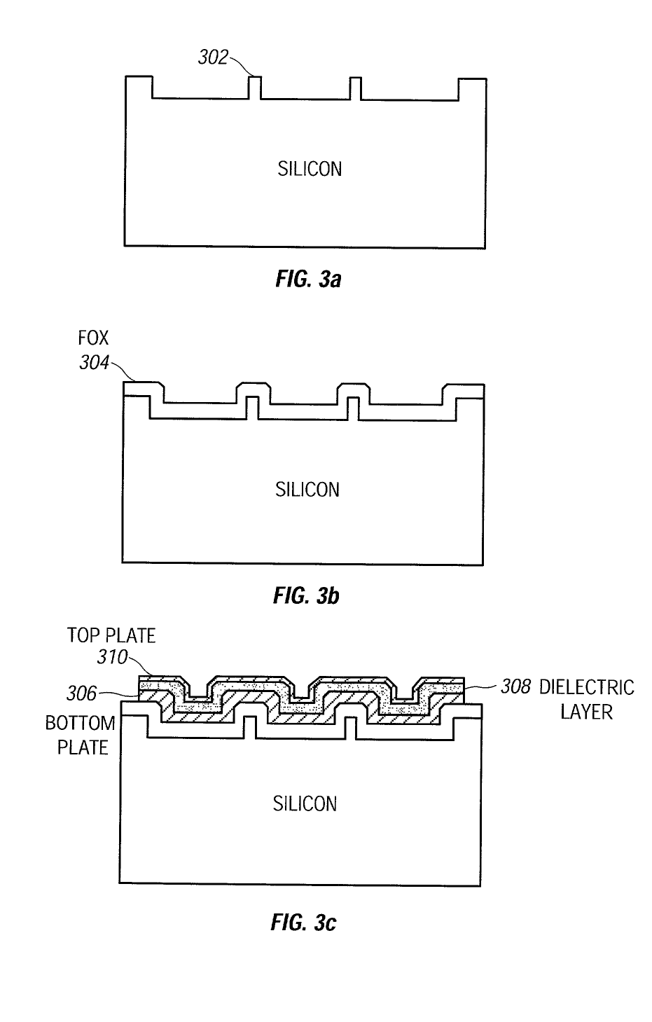

FIGS. 3a-3c show partially fabricated capacitor structures at different stages within the pole 0 approach process flow. During this phase of processing, the alignment marks are formed by etching the wafer. FIG. 3a shows a silicon surface with existing topographic or relief features 302. These features are formed on the semiconductor surface using known means, such as masking and etching the silicon at particular locations, followed by removal of the mask. In the preferred embodiment, the features are formed in an existing process step without adding a mask step to the process. The features are added using only layout modification to the existing process flow.

FIG. 3b shows the silicon substrate after formation of surface features. The recesses seen here can be made about 5 angstroms deep. A layer of field oxide 304, or FOX, is deposited over the entire surface in a thin layer. This layer insulates the capacitor from nearby devices.

FIG. 3c shows the structure after the formation of the capacitor. A bottom layer 306 for the capacitor is formed atop the FOX layer. The bottom layer is a conducting material, preferably polysilicon. The thickness of the bottom capacitor plate is about 3000A on the bottoms of the topographic features and 3000A on the sidewalls.

A dielectric layer 308 is deposited on the bottom plate 306 by means of CVD. In the preferred embodiment, the dielectric material used is SiO₂, Si₃N₄, Ta₂O₅, or Hf₂O₅ or a ferroelectric material such as PZT or BST, and the layer is 100A to 1000A thick on the bottoms, and the same thickness on the sidewalls of the topographic structures. Atop the dielectric layer is the top capacitor plate 310, formed by of polysilicon or a metallic material such as TiN, TiW, or other materials such as Al-Cu (0.5%). The top plate is 3000A thick on the bottoms with the same thickness on the sidewalls of the topographic features.

By creating a capacitor formed on the surface of topographic features, the total surface area of the capacitor is increased by 10-40%. This means that the die size using the innovations of the present application can be reduced as much as 5-12% in area. Implementing the innovative capacitor structure requires only layout modification within an existing process flow. No new masks need be added, and no expense is added to the process flow.

Not only does the innovative capacitor structure increase the capacitance (both the above mentioned embodiment and those discussed below), it also helps overcome another process difficulty that typically exists during capacitor formation. By etching recessed portions in the surface on which the capacitor is formed, some of the capacitor is created at a lower level than the silicon surface, which helps protect it from damage during contact etch. Additionally, normal capacitors for MS or analog applications are formed on the chip at a higher location or level than those of the present application. This causes a problem during the contact etch, which sometimes etches partially through or otherwise damages the top capacitor plate. By forming the capacitor lower in the circuit structure it is protected from the etch.

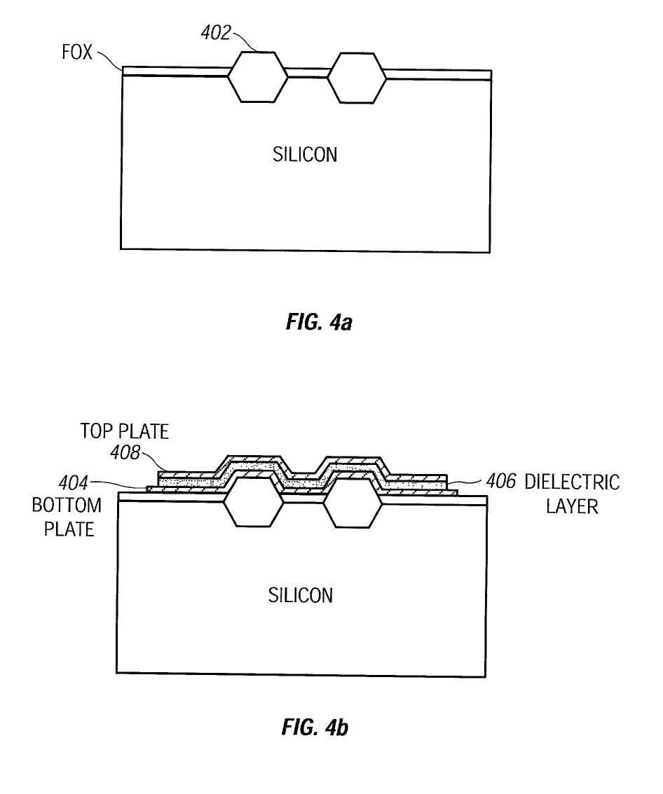

FIGS. 4a-4c show partially fabricated integrated circuit structures for fabricating the innovative capacitor structure in the well oxidation approach process flow. In this embodiment, the capacitor structure is formed during the well oxidation stage of the circuit fabrication process. During well preparation, the implant locations are patterned and the resist stripped, which is followed by oxide growth to block the implants at specific locations. During existing process steps at the well preparation level, the surface recesses are formed by modifying the design to also place and strip oxide at the area where the capacitor is to be formed. When this sacrificial oxide is removed, it creates a recess where some of the silicon itself was consumed during oxide formation. This is followed by growth of the isolation or field oxide (sometimes called FOX). The isolation oxide creates blocks of oxide on the surface (and extending beneath the surface) of the silicon. These surface features are used to form the innovative capacitor in this embodiment. As shown in the figures and discussed below, the existing process flow is used to place such oxide structures on the surface which provide surface features so that the capacitor formed thereon will not have a planar surface.

FIG. 4a shows the formation of isolating oxide masses 402. In the preferred embodiment, these are formed in a LOCOS process, but can be formed using, for example, shallow trench isolation methods as well. In the preferred embodiment, these structures are formed with only modification of existing designs and no added process steps are required.

FIG. 4b shows the silicon substrate with well oxidation relief surface features covered by the capacitor structure. The capacitor comprises a layer of conducting material 404 covered by a dielectric material 405, covered by another conducting layer 408. In the preferred embodiment, the capacitor plates are formed from polysilicon, and are about 3000A thick. The dielectric material is SiO₂, Si₃N₄, Ta₂O₅, or Hf₂O₅ or a ferroelectric material such as PZT or BST, and is deposited by CVD to a thickness of about 100A to 1000A on the tops and sidewalls of the structure.

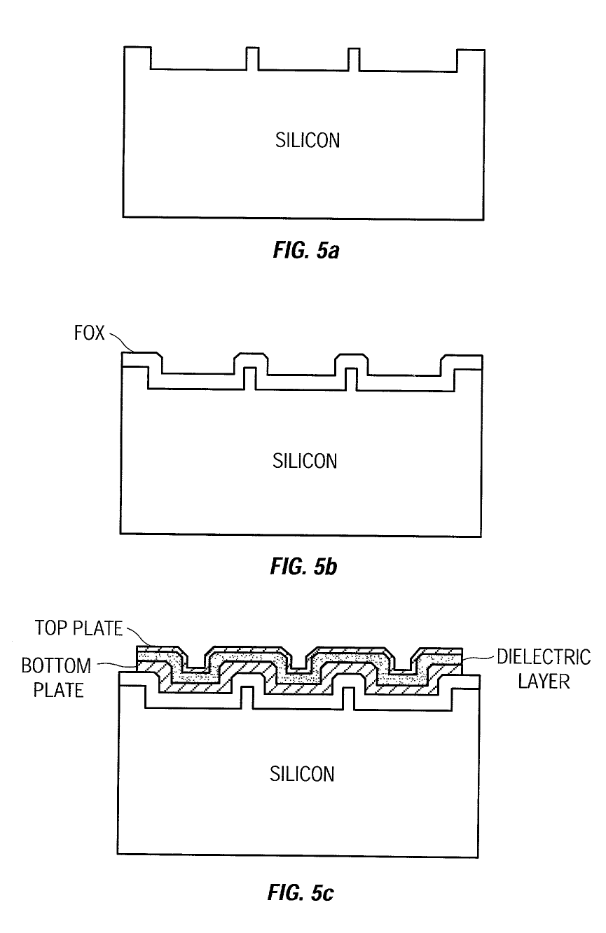

FIGS. 5a-5c show the formation of the innovative capacitor structure in the combined pole 0 and well oxidation approach process flow. This approach uses advantages of the two previously discussed examples to create surface features. In this variation, during the alignment mark placement phase of processing, the area where the capacitor is to be located is also patterned and etched, creating surface features during the step in which alignment marks are created. These are shown in FIG. 5a.

The recesses made from this step are made deeper during the well preparation phase. The oxide layer that is formed during well oxidation is also formed in the capacitor's area, consuming some of the surface silicon. Thus, when this oxide is stripped, some silicon is also removed from the surface and the surface recesses for the capacitor are made deeper, allowing greater effective area for the capacitor plates. An additional 2-3 angstroms of depth can be added to the recesses with this method over the pole 0 process method alone (shown in FIGS. 3).

FIG. 5b shows the surface after the field oxide has been formed. This oxide is subsequently stripped, deepening the recesses in the surface. FIG. 5c shows the capacitor formed on the surface features.

Of course there are other methods that may be used to produce surface features upon which to form capacitors within the contemplation of the present application. Applying different methods to the problem allows multiple choices for the design of the device, which increases integration margin.

Definitions

Following are short definitions of the usual meanings of some of the technical terms which are used in the present application. (However, those of ordinary skill will recognize whether the context requires a different meaning.) Additional definitions can be found in the standard technical dictionaries and journals.

Relief Features: features on the surface of a material that extend above the surface plane or dip below it, or both. A non-planar surface.

Topographic features: relief features. PZT: Lead zirconate-titanate, PbZrO₃TiO₃. BST: Barium Strontium Titanate, (BaSr)TiO.

Modifications and Variations

As will be recognized by those skilled in the art, the innovative concepts described in the present application can be modified and varied over a tremendous range of applications, and accordingly the scope of patented subject matter is not limited by any of the specific exemplary teachings given, but is only defined by the issued claims.

Additional general background, which help to show the knowledge of those skilled in the art regarding variations and implementations of the disclosed inventions, may be found in the following documents, all of which are hereby incorporated by reference: “Analog MOS Integrated Circuits, Part IV Successive Approximation and Parallel A/D and D/A converters,” Ed. Paul Gray, David Hodges, Robert Broderson; (Wiley, 1980).

What is claimed is:

1. A circuit structure for an analog circuit stage, comprising:
a parallel plate capacitor formed on surface features such that said capacitor is not planar.

2. The circuit structure of claim 1, wherein said capacitor has a dielectric layer between two conducting layers, said dielectric layer being SiO₂.

3. The circuit structure of claim 1, wherein said capacitor has a dielectric layer between two conducting layers, at least one of said conducting layers being polysilicon.

4. The circuit structure of claim 1, wherein said capacitor has a dielectric layer between two conducting layers, said dielectric layer being PZT.

5. The circuit structure of claim 1, wherein said features are formed by patterning and etching the surface, and wherein said features are formed simultaneously with the placement of alignment marks.

6. A circuit structure for an analog circuit stage, comprising:
a first conducting layer;
an insulating layer formed on said first conducting layer;
a second conducting layer formed on said insulating layer to thereby form a capacitor structure;
wherein said capacitor structure is formed on surface features such that said capacitor is not planar.

7. The circuit structure of claim 6, wherein said insulating layer is made of SiO₂.

8. The circuit structure of claim 6, wherein said first and said second conducting layers are made from polysilicon.

9. The circuit structure of claim 6, wherein said features are formed by patterning and etching the surface.

10. The circuit structure of claim 6, wherein said features are formed during placement of alignment marks.

11. A semiconductor fabrication method, comprising the steps of:
forming surface features simultaneously with the formation of alignment marks on a wafer;
forming a first conducting layer over said surface features;
forming an insulating layer on said first conducting layer;
forming a second conducting layer on said insulating layer to thereby form a capacitor structure;
wherein said capacitor structure is not planar.

12. The circuit structure of claim 11, wherein said insulating layer is SiO₂.

13. The circuit structure of claim 11, wherein said first and said second conducting layers are polysilicon.

14. The circuit structure of claim 11, wherein said features are formed by patterning and etching.

15. A semiconductor fabrication method, comprising the steps of:
forming a sacrificial layer of oxide on selected areas of a substrate;
stripping said sacrificial layer to form recesses in said substrate;
forming a first insulating layer on said substrate over said recesses;
forming a first conducting layer on said first insulating layer;
forming a second insulating layer on said first conducting layer;
forming a second conducting layer on said second insulating layer to thereby form a capacitor structure;
wherein said capacitor structure has non-planar surface features.

16. The circuit structure of claim 15, wherein said second insulating layer is SiO₂.

17. The circuit structure of claim 15, wherein said first and second conducting layers are polysilicon.
